(19) United States
(12) Patent Application Publication
(10) Pub. No.: US 2019/0178954 A1
(43) Pub. Date: Jun. 13, 2019

(54) Magnetoresistance Element Having Selected Characteristics To Achieve A Desired Linearity

(71) Applicant: Allegro MicroSystems, LLC, Worcester, MA (US)

(72) Inventors: Rémy Lassalle-Balier, Bures sur Yvette (FR); Jeffrey Eagen, Manchester, NH (US)

(73) Assignee: Allegro MicroSystems, LLC, Worcester, MA (US)

(21) Appl. No.: 15/837,511

(22) Filed: Dec. 11, 2017

(51) Int. Cl. G01R 33/09

(52) U.S. Cl. CPC G01R 33/093

(57) ABSTRACT

A magnetoresistance element disposed upon a substrate can include a stack of layers. The stack of layers can include a first portion including a first bias layer structure for generating a first bias magnetic field with a first bias direction, and a first free layer structure disposed proximate to the first bias layer structure, wherein the first free layer structure is biased by the first bias magnetic field. The stack of layers can also include a second portion including a second bias layer structure for generating a second bias magnetic field with a second bias direction; and a second free layer structure disposed proximate to the second bias layer structure, wherein the second free layer structure is biased by the second bias magnetic field, and wherein the first bias direction and the second bias directions are opposite to each other.

### CROSS REFERENCE TO RELATED APPLICATIONS

Not Applicable.

### STATEMENT REGARDING FEDERALLY SPONSORED RESEARCH

Not Applicable.

### FIELD OF THE INVENTION

This invention relates generally to magnetoresistance elements and, more particularly, to a magnetoresistance element having layers and formed in a shape with a selected relationship between layer magnetic field strength and shape width to achieve a desired linearity.

### BACKGROUND

As used herein, the term “magnetic field sensing element” is used to describe a variety of electronic elements that can sense a magnetic field. One such magnetic field sensing element is a magnetoresistance (MR) element. The magnetoresistance element has a resistance that changes in relation to an external magnetic field experienced by the magnetoresistance element.

As is known, there are different types of magnetoresistance elements, for example, a semiconductor magnetoresistance element such as Indium Antimonide (InSb), a giant magnetoresistance (GMR) element, an anisotropic magnetoresistance element (AMR), and a tunneling magnetoresistance (TMR) element, also called a magnetic tunnel junction (MTJ) element.

Of these magnetoresistance elements, the GMR and the TMR elements operate with spin electronics (i.e., electron spins) where the resistance is related to the magnetic orientation of different magnetic layers separated by nonmagnetic layers. In spin valve configurations, the resistance is related to an angular direction of a magnetization in a so-called “free-layer” of “free-layer structure” relative to another layer so-called “reference layer” of “reference layer structure.” The free layer and the reference layer are described more fully below.

The magnetoresistances element may be used as a single element or, alternatively, may be used as two or more magnetoresistance elements arranged in various configurations, e.g., a half bridge or full (e.g., Wheatstone) bridge.

As used herein, the term “magnetic field sensor” is used to describe a circuit that uses one or more magnetic field sensing elements, generally in combination with other circuits. In a typical magnetic field sensor, the magnetic field sensing element and the other circuits can be integrated upon a common substrate, for example, a semiconductor substrate. In some embodiments, the magnetic field sensor can also include a lead frame and packaging.

Magnetic field sensors are used in a variety of applications, including, but not limited to, an angle sensor that senses an angle of a direction of a magnetic field, a current sensor that senses a magnetic field generated by a current carried by a current-carrying conductor, a magnetic switch that senses the proximity of a ferromagnetic object, a rotation detector that senses passing ferromagnetic articles, for example, magnetic domains of a ring magnet or a ferromagnetic target (e.g., gear teeth) where the magnetic field sensor is used in combination with a back-biased or other magnet, and a magnetic field sensor that senses a magnetic field density of a magnetic field.

Various parameters characterize the performance of magnetic field sensors and magnetic field sensing elements. With regard to magnetic field sensing elements, the parameters include sensitivity, which is the change in the output signal (or resistance) of a magnetic field sensing element in response to an external magnetic field, and linearity, which is the degree to which the output signal (or resistance) of a magnetic field sensing element varies linearly (i.e., in direct proportion) to the external magnetic field. The parameters also include offset, which describes and output (or resistance) from the magnetic field sensing element that is not indicative of zero magnetic field when the magnetic field sensing element experiences a zero magnetic field. The parameters also include common mode rejection, which describes a change in behavior when the magnetic field sensor experiences a large (common mode) external magnetic field.

GMR and TMR elements are known to have a relatively high sensitivity, compared, for example, to Hall Effect elements. TMR elements are known to have a higher sensitivity than GMR elements, but at the expense of higher noise at low frequencies.

Both GMR and TMR elements (magnetoresistance elements) are known to suffer from saturation at magnetic fields above a threshold level. Thus, conventional GMR and TMR elements have one linear range in response to magnetic fields, the one linear range between upper and lower saturation regions.

In some applications, it would be desirable to provide a magnetoresistance element that can have a different linear range, for example, an extended linear range or more than one linear range between saturation regions.

### SUMMARY

The present invention provides a magnetoresistance element that can have a different linear range, for example, an extended linear range or more than one linear range between saturation regions.

In accordance with an example useful for understanding an aspect of the present invention, a magnetoresistance element disposed upon a substrate can include a stack of layers. The stack of layers can include a first portion including a first bias layer structure for generating a first bias magnetic field with a first bias direction, and a first free layer structure disposed proximate to the first bias layer structure, wherein the first free layer structure is biased by the first bias magnetic field. The stack of layers can also include a second portion including a second bias layer structure for generating a second bias magnetic field with a second bias direction, and a second free layer structure disposed proximate to the second bias layer structure, wherein the second free layer structure is biased by the second bias magnetic field, and wherein the first bias direction and the second bias directions are opposite to each other. The magnetoresistance element can further include a shape having a longest dimension and a shortest dimension both parallel to the substrate, wherein the first and second bias magnetic fields are within +/− twenty-five degrees of parallel to the shortest dimension.

In some embodiments, the above magnetoresistance element can include one or more of the following aspects in any combination.

In some embodiments of the above magnetoresistance element, the first portion comprises a first resistance-to-external-magnetic-field transfer function having a first linear range of external magnetic fields and wherein the second portion comprises a second resistance-to-external-magnetic-field transfer function having a second linear range of external magnetic fields, the first and second linear ranges having an overlap in a direction of external magnetic fields, the overlap less than eighty-five percent of the first linear range and less than eighty-five percent of the second linear range, and the magnetoresistance element further includes a third resistance-to-external-magnetic-field transfer function different than the first and second resistance-to-external-magnetic-field transfer functions.

In some embodiments of the above magnetoresistance element, a combination of the shortest dimension and magnitudes of the first and second bias magnetic fields is selected to result in the overlap.

In some embodiments of the above magnetoresistance element, the first and second bias magnetic field directions are parallel to the shortest dimension.

In some embodiments of the above magnetoresistance element, the second portion is disposed under the first portion in a direction perpendicular to a major surface of the substrate.

In some embodiments of the above magnetoresistance element, the shortest dimension and magnitudes of the first and second bias magnetic fields are selected to result in the third resistance-to-external-magnetic-field transfer function having first, second, and third linear regions, the first linear region associated with a first range of external magnetic fields, the second linear region associated with a second range of external magnetic fields, and the third linear region associated with a third range of external magnetic fields, the first, second, and third ranges being different ranges, a center of the second range between the first and third ranges.

In some embodiments of the above magnetoresistance element, the second linear region has a slope greater than one hundred fifty percent of slopes of the first and third linear regions.

In some embodiments of the above magnetoresistance element, the shortest dimension and magnitudes of the first and second bias magnetic fields are selected to result in the third resistance-to-external-magnetic-field transfer function having a linear region greater than one hundred fifty percent of the first linear range of the first resistance-to-external-magnetic-field transfer function and also greater than one hundred fifty percent of the second linear range of the second resistance-to-external-magnetic-field transfer function.

In some embodiments of the above magnetoresistance element, the third resistance-to-external-magnetic-field transfer function has only one linear region.

In some embodiments of the above magnetoresistance element, the shortest dimension and magnitudes of the first and second bias magnetic fields are selected to result in the third resistance-to-external-magnetic-field transfer function having first and second linear regions, the first linear region associated with a first range of external magnetic fields and the second linear region associated with a second range of external magnetic fields, the first and second linear ranges being different and non-overlapping linear ranges,

In some embodiments of the above magnetoresistance element, the first and second linear regions have equal slopes.

In some embodiments of the above magnetoresistance element, the shape comprises a yoke shape.

In some embodiments of the above magnetoresistance element, the second portion is disposed under the first portion in a direction perpendicular to a major surface of the substrate.

### BRIEF DESCRIPTION OF THE DRAWINGS

The foregoing features of the invention, as well as the invention itself may be more fully understood from the following detailed description of the drawings, in which:

FIG. 1 is a block diagram showing layers of an illustrative giant magnetoresistance (GMR) element having two double pinned GMR element portions;

FIG. 2 is a block diagram showing a top view of a GMR element having a yoke shape;

FIG. 3 is a block diagram showing another top view of a GMR element having a yoke shape;

FIG. 4 is a graph showing a resistance-versus-external-magnetic-field transfer function and a sensitivity-versus-external-magnetic-field transfer function versus magnetic field of a conventional GMR element;

FIG. 5 is a graph showing a resistance-versus-external-magnetic-field transfer function and a sensitivity-versus-external-magnetic-field transfer function of an illustrative GMR element;

FIG. 6 is a graph showing a resistance-versus-external-magnetic-field transfer function and a sensitivity-versus-external-magnetic-field transfer function of another illustrative GMR element;

FIG. 7 is a graph showing a resistance-versus-external-magnetic-field transfer function and a sensitivity-versus-external-magnetic-field transfer function of another illustrative GMR element;

FIG. 8 is a graph showing three regions of yoke width versus bias magnetic field;

FIG. 9 is a graph showing two resistance-versus-external-magnetic-field transfer functions with large overlap and small separation and combined to generate another resistance-versus-external-magnetic-field field transfer function;

FIG. 10 is a graph showing two resistance-versus-external-magnetic-field transfer functions with a smaller overlap and larger separation, also combined to generate another resistance-versus-external-magnetic-field field transfer function;

FIG. 11 is a graph showing two resistance-versus-external-magnetic-field transfer functions with no overlap and still larger separation, also combined to generate another resistance-versus-external-magnetic-field field transfer function; and

FIG. 12 is a graph showing two resistance-versus-external-magnetic-field transfer functions also with no overlap and still larger separation, also combined to generate another resistance-versus-external-magnetic-field field transfer function.

### DETAILED DESCRIPTION

Before describing the present invention, it should be noted that reference is sometimes made herein to GMR elements having particular shapes (e.g., yoke shaped). One of ordinary skill in the art will appreciate, however, that the techniques described herein are applicable to a variety of sizes and shapes. TMR elements having other shapes are also possible.

As used herein, the term “magnetic field sensing element” is used to describe a variety of different types of electronic elements that can sense a magnetic field. A magnetoresistance element is but one type of magnetic field sensing element.

As is known, there are different types of magnetoresistance elements, for example, a semiconductor magnetoresistance element such as Indium Antimonide (InSb), a giant magnetoresistance (GMR) element, an anisotropic magnetoresistance element (AMR), and a tunneling magnetoresistance (TMR) element, also called a magnetic tunnel junction (MTJ) element.

As is known, metal based or metallic magnetoresistance elements (e.g., GMR, TMR, AMR) tend to have axes of sensitivity parallel to a substrate.

As used herein, the term “magnetic field sensor” is used to describe a circuit that uses a magnetic field sensing element, generally in combination with other circuits. Magnetic field sensors are used in a variety of applications, including, but not limited to, an angle sensor that senses an angle of a direction of a magnetic field, a current sensor that senses a magnetic field generated by a current carried by a current-carrying conductor, a magnetic switch that senses the proximity of a ferromagnetic object, a rotation detector that senses passing ferromagnetic articles, for example, magnetic domains of a ring magnet or a ferromagnetic target (e.g., gear teeth) where the magnetic field sensor is used in combination with a back-biased or other magnet, and a magnetic field sensor that senses a magnetic field density of a magnetic field.

The terms “parallel” and “perpendicular” are used in various contexts herein. It should be understood that the terms parallel and perpendicular do not require exact perpendicularity or exact parallelism, but instead it is intended that normal manufacturing tolerances apply, which tolerances depend upon the context in which the terms are used.

As used herein, the term “predetermined,” when referring to a value or signal, is used to refer to a value or signal that is set, or fixed, in the factory at the time of manufacture, or by external means, e.g., programming, thereafter. As used herein, the term “determined,” when referring to a value or signal, is used to refer to a value or signal that is identified by a circuit during operation, after manufacture.

While GMR elements may be used in examples herein, the same concepts apply to TMR elements, but which, rather than references yoke width, references to a smallest dimension of a shape (e.g., a rectangular shape) parallel to a substrate of a TMR pillar is possible.

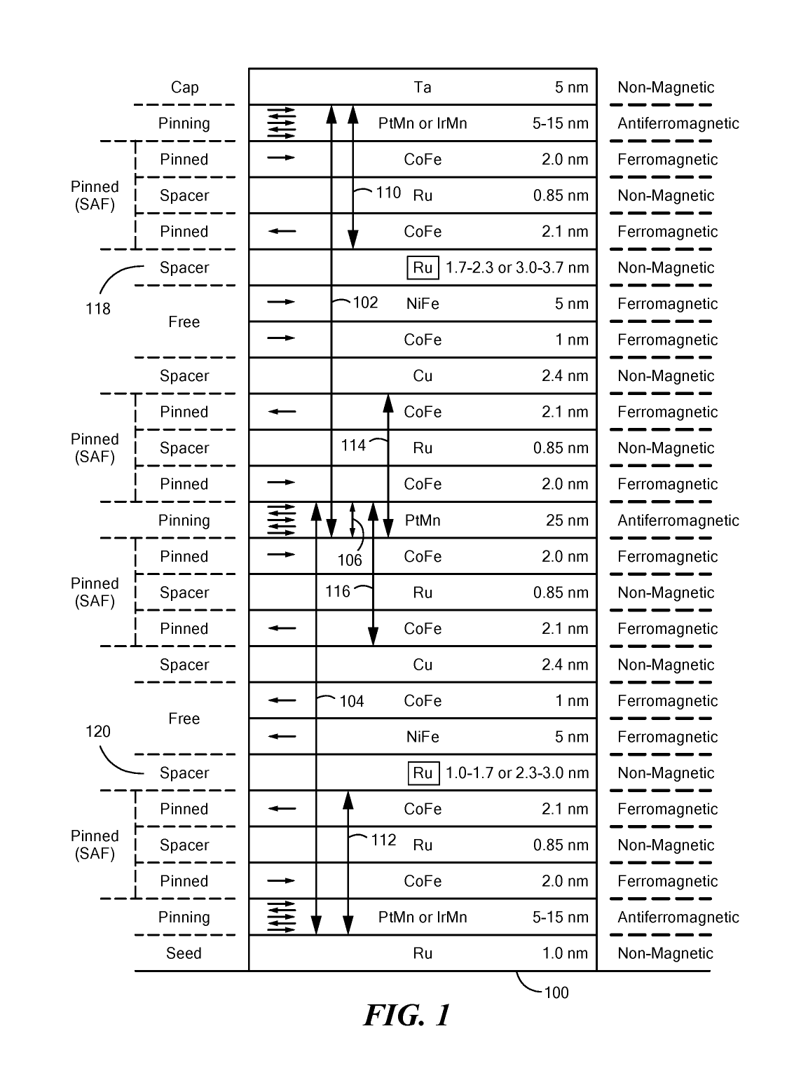

Referring now to FIG. 1, a dual magnetoresistance element 100 includes a first portion 102 and also a second portion 104, each portion being a double pinned GMR element having two pinning layers and two pinned layer structures, the two portions 102, 104 coupled essentially in parallel for a magnetoresistance element (e.g., a GMR element) in which current flows between right and left on the page, i.e., parallel to a substrate upon with the magnetoresistance element 100 is formed, or in series for a magnetoresistance element (e.g., a TMR element) in which current flows between top and bottom of the page. A common antiferromagnetic pinning layer 106 can be in the middle, and used in both the first and second portions 102, 104.

The first portion 102 can include a first reference layer structure 114 and a first bias layer structure 110. The second portion 104 can include a second reference layer structure 116 and a second bias layer structure 112. In an alternate embodiment, the first reference layers structure 114 and the first bias layer structure 110 can be interchanged in position and the second reference layer structure 116 and the second bias layer structure 112 can also be interchanged in position.

The dual spin valve magnetoresistance element 100 can have two free layer structures. Spacer layers 118, 120 can have different thicknesses selected to result in different couplings to the free layer structures so that the two free layer structures have magnetic fields with opposite directions as shown. The directions of the magnetic fields in the two free layer structures can both be reversed from the direction shown.

In some embodiments, the spacer layer 120 can have a thickness that can be in one of two example ranges, e.g., about 1.0 nm to about 1.7 nm or about 2.3 nm to about 3.0 nm, to result in a ferromagnetic coupling across the spacer layer 120

In some embodiments, the spacer layer 118 has a thickness that can be in the other one of two example ranges, e.g., about 1.7 nm to about 2.3 nm or about 3.0 nm to about 3.7 nm, to result in an antiferromagnetic coupling across spacer layer 118.

Thus, it will be appreciated that the two free layer structures experience bias magnetic fields generated by the first and second bias layer structures 110, 112, respectively, with nominal directions that are parallel to each other but in opposite directions.

In addition, by selection of thickness of the two spacer layers 118, 120, the two couplings, antiferromagnetic and ferromagnetic, the two free layer structures can experience about the same magnitude of bias magnetic fields generated by the bias layer structures 110, 112, but in opposite directions.

It should be further appreciated that operation of the dual spin valve magnetoresistance element 100 operates very much like combination of two separate magnetoresistance elements, but where two resulting spacer layers 118, 120 have selected thickness to result in a ferromagnetic coupling to the one free layer structure and an antiferromagnetic coupling to the other free layer structure. Thus, in some alternate embodiments, the dual double pinned magnetoresistance element 100 can be replaced by two double pinned magnetoresistance elements electrically coupled together.

In some alternate embodiments, the spacer layer 118 can have the thickness of the spacer layer 120 and vice versa.

The dual magnetoresistance element 100 has four synthetic antiferromagnetic (SAF) pinned structures. Thus, the first and second portions 102, 104 are two double pinned structures within the dual magnetoresistance element 100.

The four synthetic antiferromagnetic (SAF) structures are referred to herein as pinned layer structures.

While particular layer thicknesses are shown in FIG. 1, it will be understood that the thicknesses of some or all layers can be different.

While particular sequences of layers are shown in FIG. 1, it should be appreciated that there can be other interposing layers, for example, other spacer layers, between any two or more of the layers shown. Also, there can be other layers above or below the layers shown in FIG. 1.

The term “over,” when describing layers that are over each other, is used to indicate a sequence of layers, but not to indicate that layers are necessarily in direct contact. Layers that are over each other can include layers that interpose with each other.

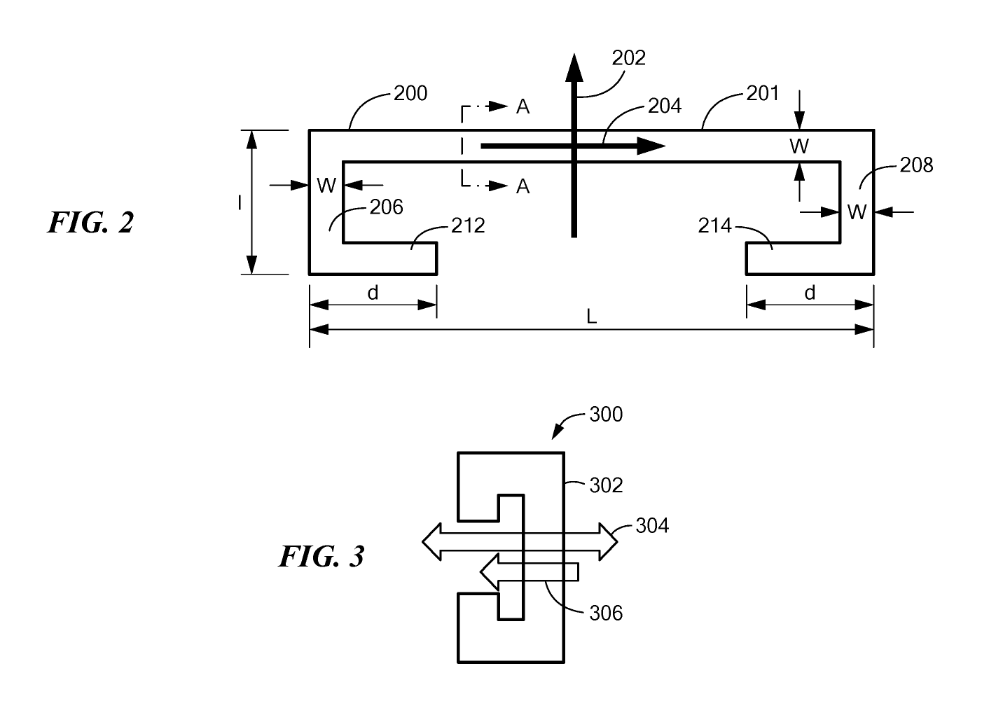

Referring now to FIG. 2, according to one embodiment, the magnetoresistance element 100 of FIG. 1 can be formed in the shape of a yoke 200 (top view). A section line A-A shows the perspective FIG. 1.

The yoke 200 has a main part 201, two arms 206, 208 coupled to the main part 201, and two lateral arms 212, 214 coupled to the two arms 206, 208, respectively. In some embodiments, the main part 201, the two arms 206, 208, and the two lateral arms 212, 214 each have a width (w). However, in other embodiments, the widths can be different.

A length (L) of the yoke 200 and a length (d) of the lateral arms 212, 214 of the yoke 200 are each at least three times the width (w) of the yoke 200, and the width (w) of the yoke 200 can be between about one μm and about twenty μm.

As used herein, when referring to magnetoresistance elements, the term “transverse” is used to refer to a magnetic field perpendicular to a longer dimension of the yoke 200 of FIG. 2, e.g., in a direction of the arrow 202 of FIG. 2. The transverse direction 202 can also be generally parallel to a direction of the bias magnetic fields experienced by the free layer structures of the dual magnetoresistance element 100 of FIG. 1. However, the bias magnetic fields can be within about +/− twenty-five degrees, within about +/− ten degrees or within +/− five degrees of the transverse direction. 202 (i.e., the shortest dimension, width w.).

As used herein, when referring to magnetoresistance elements, the term “longitudinal” is used to refer to a magnetic field parallel to a longer dimension of the yoke 200 of FIG. 2, e.g., in a direction of the arrow 204 of FIG. 2. The longitudinal direction 204 can also be generally perpendicular to a direction of the bias magnetic fields experienced by the free layer structures of the dual magnetoresistance element 100 of FIG. 1.

A maximum response axis is parallel to the arrow 202.
The yoke dimensions can be, for example, within the following ranges:
   the length (L) of the main part 201 of the yoke 200 can be between about ten μm and ten millimeters;
   the length (1) of the arms 206, 208 of the yoke 200 can be at least three times the width (w);
   the width (w) of the yoke 200 can be between about one hundred nanometers and about twenty μm, with particular examples described in conjunction with FIGS. 10-12 below.

The arms 206, 208 of the yoke 200 are linked to the lateral arms 212, 214, which are parallel to the main part 201, and have a length 1 which is between about ¼ and ⅓ of the overall length (L).

In general, sensitivity of the magnetoresistance element 100 having the yoke shape 200 decreases with the width (w), and the low frequency noise of the magnetoresistance element 100 increases with the width (w).

The yoke shape offers better magnetic homogeneity in a longitudinally central area of the main part 201.

For a GMR element, the overall stack can be designed in a yoke shape, but for a TMR element, in some embodiments, the TMR element can have a shape (e.g., rectangular) that has a longest dimension and a shortest dimension both parallel to a substrate.

Referring now to FIG. 3, a yoke 300 can have a main part 302. Where the yoke 300 has the layers of the dual magnetoresistance element 100 of FIG. 1, an arrow 306 is indicative of a magnetic direction of the first and second reference layer structures 114, 116 of FIG. 1, both pointing to the left at pinned layers proximate to Cu spacer layers. Two directions of an arrow 304 are indicative of two directions of bias magnetic fields experienced by the two free layers structures of the magnetoresistance element 100 of FIG. 1.

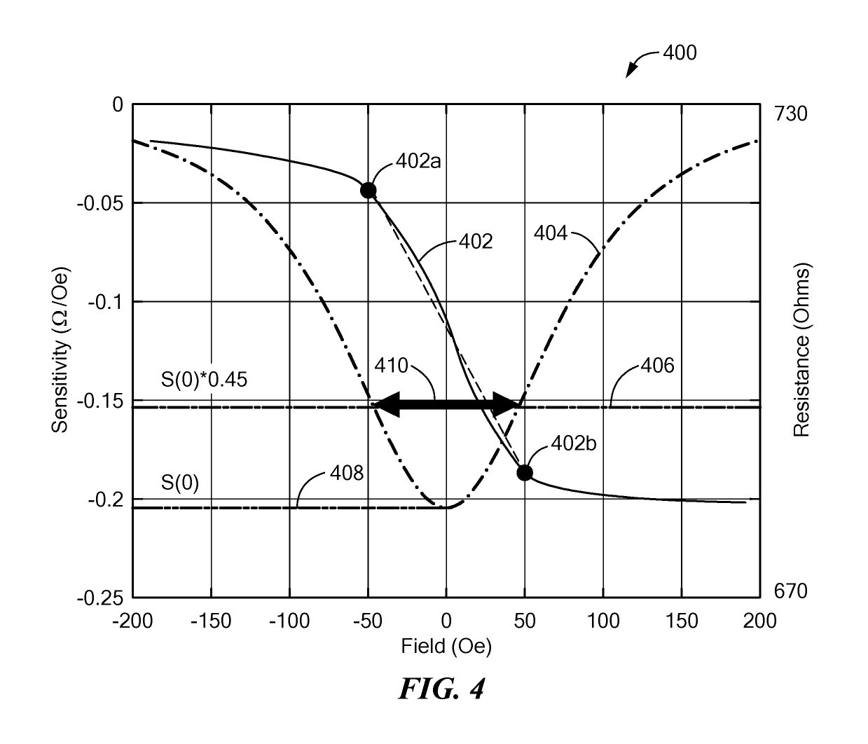

Referring now to FIG. 4, a graph 400 has a horizontal axis with a scale in units of magnetic field in Oersteds of an external magnetic field. The graph 400 also has a left vertical axis with a scale in units of sensitivity in ohms per Oersted. The graph 400 also has a right vertical axis with a scale in units of resistance in ohms.

A curve 402 uses the right vertical scale and is indicative of a resistance-versus-external-magnetic-field transfer function (or simply a resistance transfer function) of a general GMR element. A curve 404 uses the left vertical scale and is indicative of a sensitivity-versus-external-magnetic-field transfer function (or simply a sensitivity transfer function) of the general GMR element.

A linear range of the curve 402 can be defined to exist in a range 410 of the curve 404 in which a sensitivity changes, for example, by twenty-five-five percent, from a baseline sensitivity, for example, from a maximum sensitivity of the GMR element, here about −0.2 ohms per Oersted, which occurs at zero Oersteds. The twenty-five percent change, or a change to seventy-five percent of the baseline, here about −0.15 ohms per Oersted, is illustrated as a line 406 and a line 410. Thus, in this example, the linear range extends within about +/− fifty Oersteds of external magnetic field. Points 402a, 402b are along the resistance transfer function 402 at the same +/− fifty Oersteds.

Other percentages can also be used.

It should be understood that the resistance-versus-external-magnetic-field transfer function curve 402 and the sensitivity-versus-external-magnetic-field transfer function curve 404 are related by a slope, i.e., values of the sensitivity curve 404 according to slope(s) of the resistance curve 402.

It has been identified the linear range and the shape of the linear range can be influenced by a width of a yoke, e.g., width W of the yoke 200 of FIG. 2 and by magnitudes of bias magnetic fields experienced by free layer structures, e.g., the magnitude of bias magnetic fields experienced by the free layer structures of the magnetoresistance element 100 of FIG. 1.

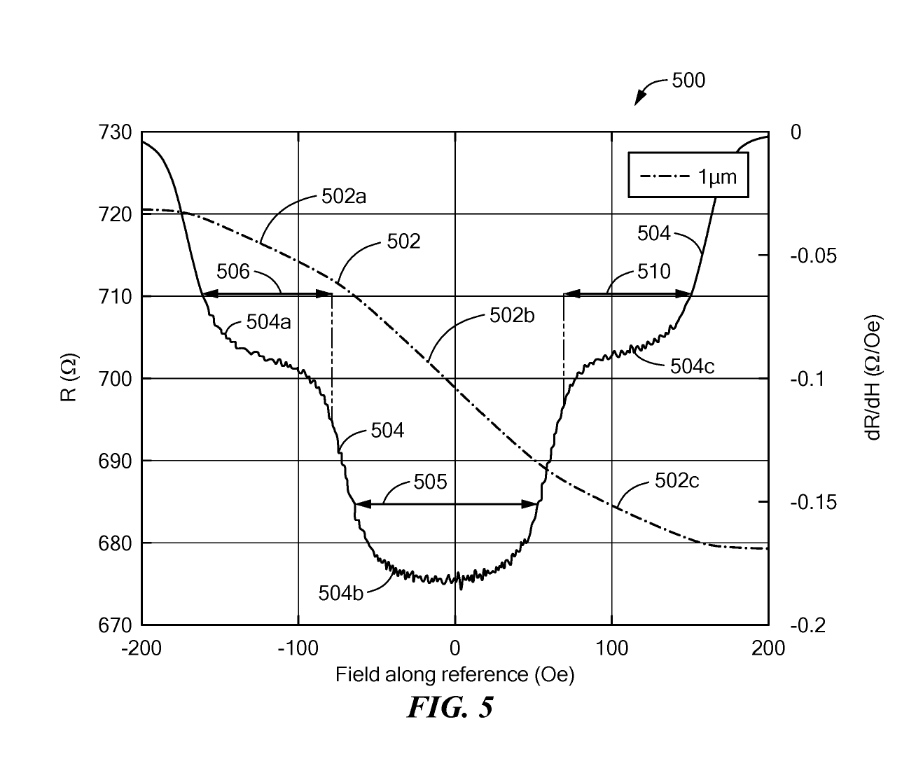

FIGS. 5-7 show resistance-versus-external-magnetic-field transfer functions and sensitivity-versus-external-magnetic-field transfer functions for the magnetoresistance element of 100 of FIG. 1 formed in a yoke shape according to FIGS. 2 and 3, but for altered magnetoresistance elements, in which the width W of the yoke 200 of FIG. 2 and magnitude of bias magnetic fields experienced by the free layer structures of the magnetoresistance element 100 of FIG. 1 are tailored in particular ways to achieve particular types of transfer functions.

FIGS. 5-7 show respective graphs 500, 600, 700, in which each has a respective horizontal axis with a scale in units of magnetic field in Oersteds of an external magnetic field. The graphs 8500, 600, 700 also each have a respective left vertical axis with a scale in units of sensitivity in ohms per Oersted. The graphs 800, 900, 1000 also each have a respective right vertical axis with a scale in units of resistance in ohms.

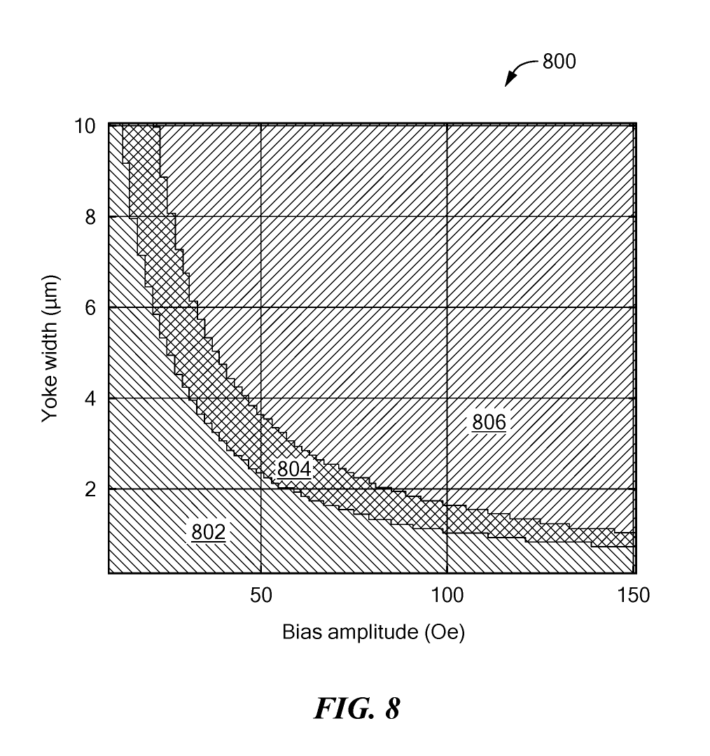

Referring now to FIG. 5, a curve 504 shows a sensitivity-versus-external-magnetic-field transfer function of a particular example of a magnetoresistance element like the magnetoresistance element 100 of FIG. 1, where the maximum response axis of the magnetoresistance element is along the transverse direction 202 of the yoke 200 of FIG. 2. A curve 502 shows a resistance-to-external-magnetic-field transfer function for the magnetoresistance element 100 of FIG. 1. In this particular example, magnetoresistance element 100 has a yoke shape that has a width of one micron and a magnitude of bias magnetic fields experienced by the free layer structures of about seventy-five Oersteds. (see also FIG. 8)

Using the definition of linear range according to FIG. 4, e.g., a change of sensitivity by +/− twenty-five percent from a baseline level (e.g., a highest or a constant sensitivity), the curve 504 can be seen to have a first linear range 506, a second linear range 505, and a third linear range 510, using baseline levels at curve portions 504a, 504b, 504c, respectively. The first linear range 506 can correspond to a first linear region 502a, the second linear range 505 can correspond to a second linear region 502b, and the third linear range 510 can correspond to a third linear region 502c of the curve 502.

The first and third linear regions 502a, 502c can have a sensitivity, i.e., a slope, that is about one half of the sensitivity of the second linear region 502b. The linear regions 502a, 502b, 502c are further described below in conjunction with FIG. 10.

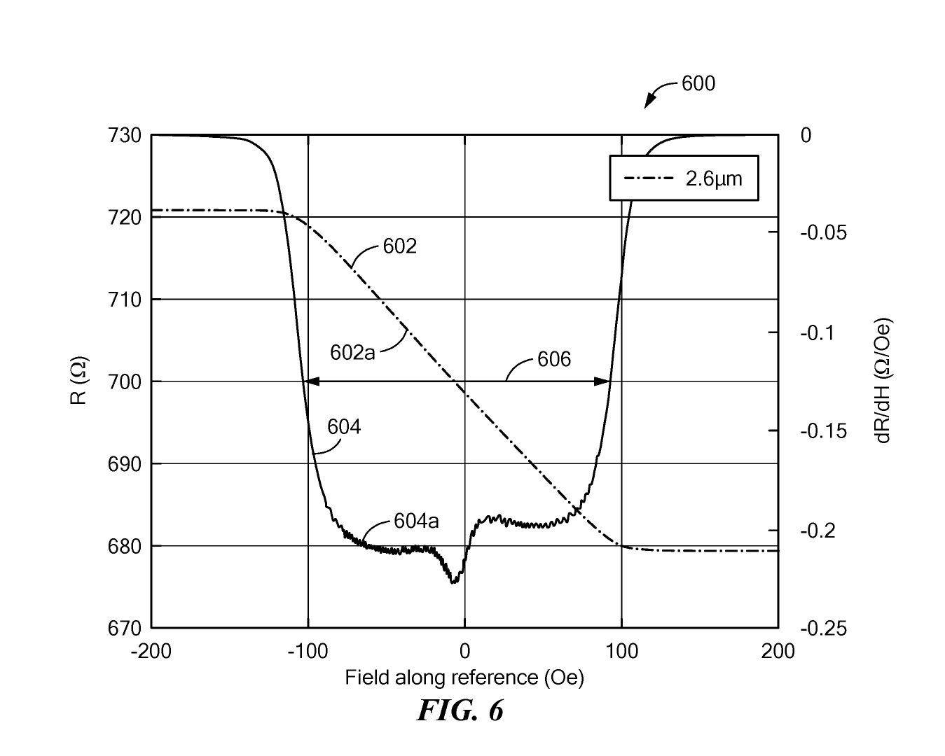

Referring now to FIG. 6, a curve 604 shows a sensitivity-to-external-magnetic-field transfer function of a particular example of a magnetoresistance element like the magnetoresistance element 100 of FIG. 1, where the maximum response axis of the magnetoresistance element 100 is along the transverse direction 202 of the yoke 200 of FIG. 2. A curve 602 shows a resistance-versus-external-magnetic-field transfer function for the magnetoresistance element 100 of FIG. 1. In this particular example, magnetoresistance element 100 has a yoke shape that has a width of 2.6 microns and a magnitude of bias magnetic fields experienced by the free layer structures of about seventy-five Oersteds. (see also FIG. 8)

Using the definition of linear range according to FIG. 4, e.g., a change of sensitivity by +/− twenty-five percent from a baseline level, the curve 602 can be seen to have a linear range 606 using a baseline level near curve portions 604a. The linear range 606 can correspond to a linear region 602a.

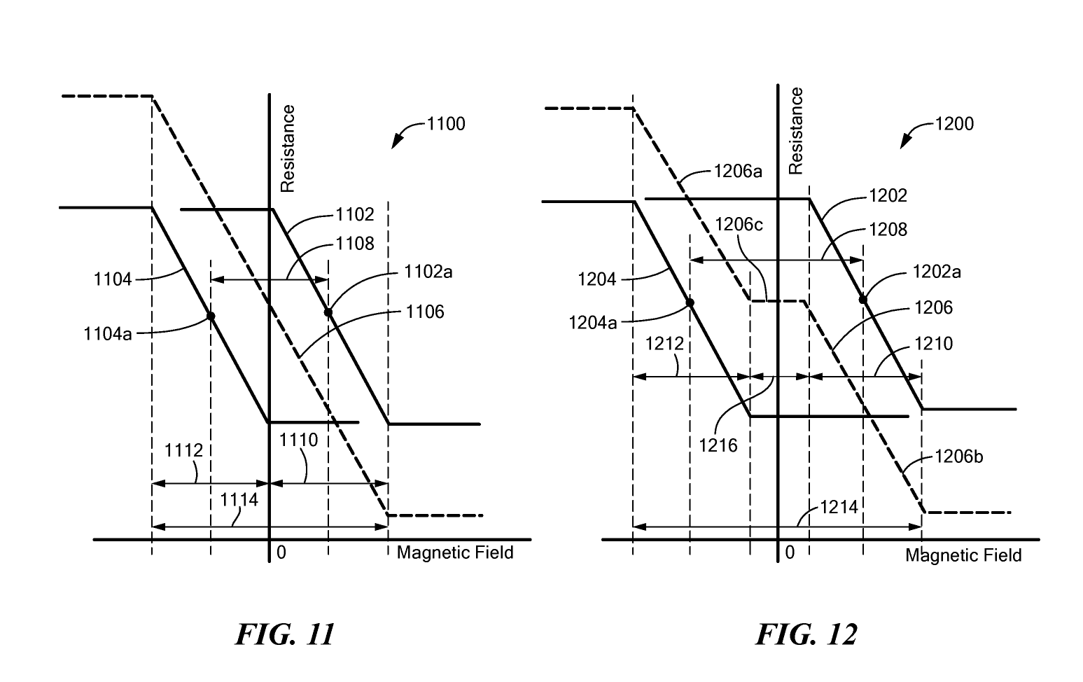

The linear regions 602a can have a sensitivity, i.e., a slope, that extends about twice as far along the horizontal axis than does a conventional magnetoresistance element. The linear region 602a is further described below in conjunction with FIG. 11.

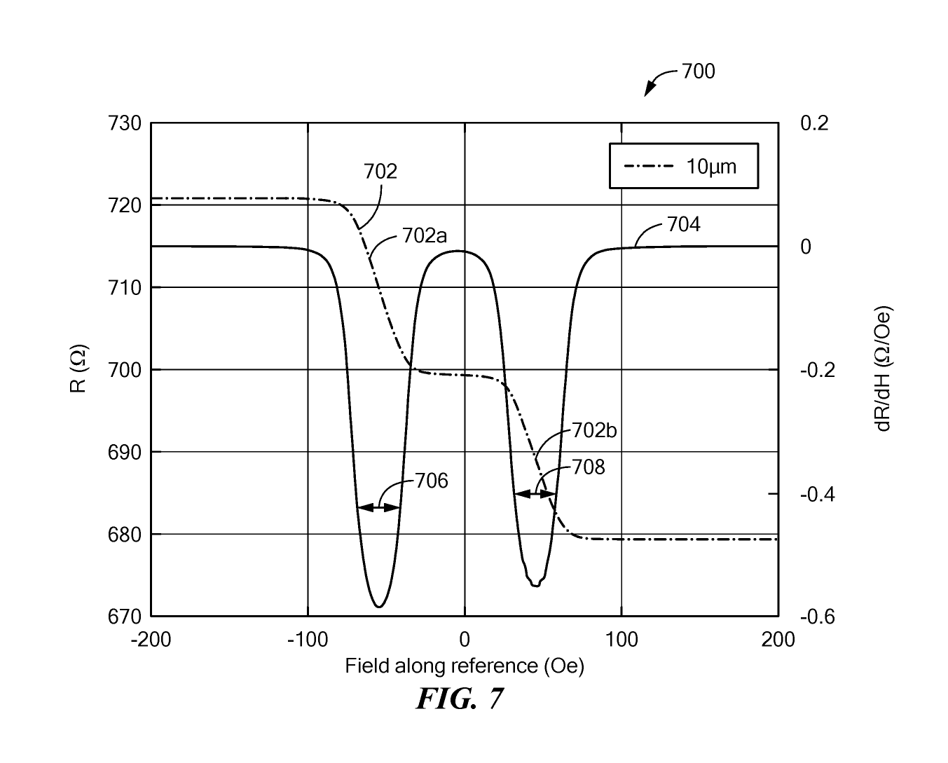

Referring now to FIG. 7, a curve 704 shows a sensitivity-versus-external-magnetic-field transfer function of a particular example of a magnetoresistance element like the magnetoresistance element 100 of FIG. 1, where the maximum response axis of the magnetoresistance element 100 is along the transverse direction 202 of the yoke 200 of FIG. 2. A curve 702 shows a resistance-versus-external-magnetic-field transfer function for the magnetoresistance element 100 of FIG. 1. In this particular example, magnetoresistance element 100 has a yoke shape that has a width of ten microns and a magnitude of bias magnetic fields experienced by the free layer structures of about seventy-five Oersteds. (see also FIG. 8)

Using the definition of linear range according to FIG. 4, e.g., a change of sensitivity by +/− twenty-five percent from a baseline level (near the two regions with sensitivity of about −0.55 ohms per Oersted), the curve 704 can be seen to have a first linear range 706 and a second linear range 708. The first linear range 706 can correspond to a first linear region 702a and the second linear range 708 can correspond to a second linear region 702b.

The linear regions 702a, 702b are further described below in conjunction with FIG. 12.

Referring now to FIG. 8, a graph 800 has a horizontal axis with a scale in units of bias magnetic field experienced by the free layer structures of the magnetoresistance element 100 of FIG. 1, in Oersteds. The graph 800 also has a vertical axis with a scale in units of yoke width according to the yoke 200 of FIG. 2.

A first region 802 can correspond to combinations of bias magnetic fields experienced by the free layer structures and yoke widths that can achieve the first, second, and third linear regions of the curve 502 of FIG. 5.

A second region 804 can correspond to combinations of free layer structure magnetic fields and yoke widths that can achieve the broader linear region of the curve 602 of FIG. 6.

A third region 806 can correspond to combinations of free layer structure magnetic fields and yoke widths that can achieve the first and second linear regions of the curve 702 of FIG. 7.

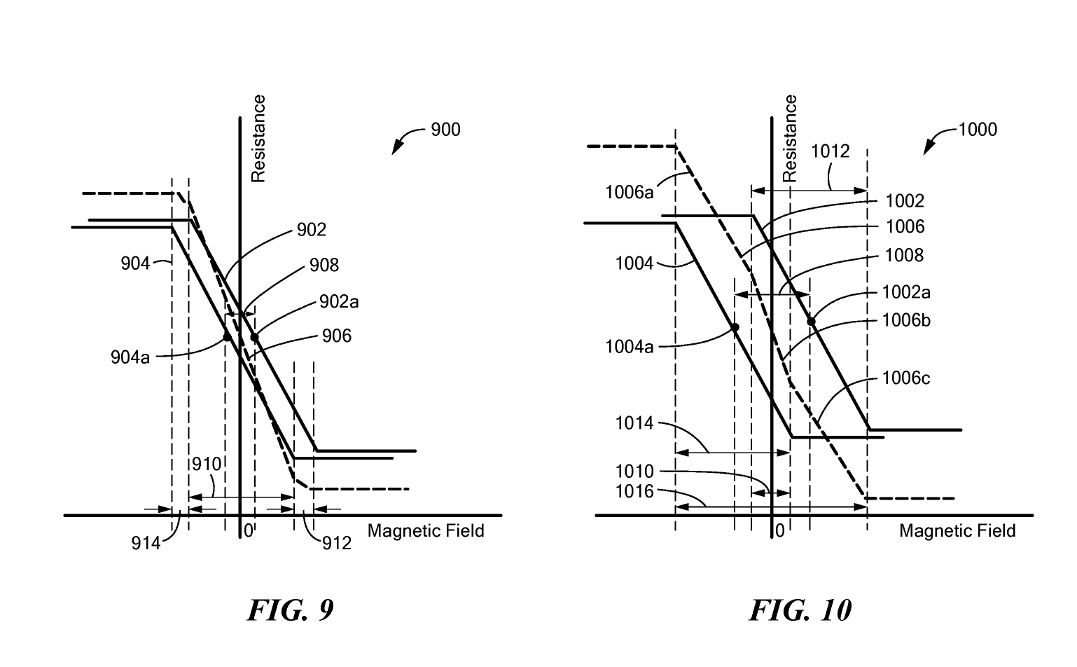

FIGS. 9-12 each show a respective resistance-versus-external-magnetic-field transfer function, namely, transfer functions for the first portion 102, for the second portion 104, and for the entire magnetoresistance element 100 of FIG. 1. In this way, it will become apparent that the separation (offset) of the transfer functions of the first and second portions 102, 104 can result in different linear regions for the magnetoresistance element 100 of FIG. 1.

Transfer functions shown in FIGS. 9-12 are shown to be somewhat ideal merely for clarity, in that the transfer functions have abrupt changes of slope to upper and lower saturation regions. In accordance with FIG. 4, it will be understood that the transitions are more gradual in an actual magnetoresistance element.

FIGS. 9-12 each have a respective horizontal axis with units of external magnetic field in Oersted and a vertical axis with units of resistance in arbitrary units.

Referring now to FIG. 9, a graph 900 includes a first curve 902 indicative of a resistance transfer function of the first portion 102 of FIG. 1. The graph 900 also includes a second curve 904 indicative of a resistance transfer function of the second portion 104 of FIG. 1. The graph 900 also includes a third curve 906 indicative of a resistance transfer function of the first portion 102 and the second portion 104 taken together in series, i.e., the entire magnetoresistance element 100 of FIG. 1.

The curve 902 has a center point 902a midway along a linear portion of the curve 902. The curve 904 has a center point 904a midway along a linear portion of the curve 904. An arrow 908 is indicative of a separation (offset) of the center points 902a, 904a.

The arrow 908 is indicative of a small separation between the center points 902a, 904a, i.e., a small separation between the curves 902, 904.

An arrow 910 is indicative of regions of the first and second curves 902, 904 for which the linear regions overlap. It should be understood that separation 908 and overlap 910, if changed, change in opposite directions.

The curve 906, within the overlapping region 910, has a slope, i.e., a sensitivity, that is double the slopes of the curves 902, 904.

Arrows 912, 914 are indicative of minor linear ranges of the curve 906 having little extent in external magnetic field. In the minor linear ranges 912, 914 one of the curves 902, 904 has a slope and the other does not. Thus, within the minor linear ranges 912, 914, the slope of the curve 906 is the same as a slope of either one of the curves 902, 904.

In this example, the minor linear ranges 912, 914 are insignificant. In conventional arrangements, ideally the curves 902, 904 would be on top of each other, in which case, the minor linear ranges 912, 914 would not exist.

Referring now to FIG. 10, a graph 1000 includes a first curve 1002 indicative of a resistance transfer function of the first portion 102 of FIG. 1. The graph 1000 also includes a second curve 1004 indicative of a resistance transfer function of the second portion 104 of FIG. 1. The graph 1000 also includes a third curve 1006 indicative of a resistance transfer function of the first portion 102 and the second portion 104 taken together in series, i.e., the entire magnetoresistance element 100 of FIG. 1.

The curve 1002 has a center point 1002a midway along a linear portion of the curve 1002. The curve 1004 has a center point 1004a midway along a linear portion of the curve 1004.

An arrow 1008 is indicative of a separation (offset) of the center points 1002a, 1004a. The separation 1008 is larger than the separation 908 of FIG. 9.

An arrow 1012 is indicative of a linear range of the first curve 1002. An arrow 1014 is indicative of a linear range of the second curve 1004.

An arrow 1010 is indicative of regions of the first and second curves 1002, 1004 for which the linear regions overlap. The arrow 1010 is indicative of a small overlap of the linear regions of the curves 1002, 1004. In some embodiments, the overlap 1010 is less than eighty-five percent of a linear range of both of the first and second curves 1002, 1004. In some embodiments, the overlap 1010 is less than fifty percent of a linear range of both of the first and second curves 1002, 1004. In some embodiments, the overlap 1010 is less than twenty-five percent of a linear range of both of the first and second curves 1002, 1004.

The curve 1006 has first, second, and third linear regions 1006a, 1006b, 1006c, respectively. Within the overlapping region 1010, a slope, i.e., a sensitivity, of the second linear region 1006b is double the slopes of the linear regions 1012, 1014 of curves 1002, 1004. Slopes, i.e., sensitivities, within the first and third linear regions 1006a, 1006c, can be the same the slopes of the linear regions of curves 1002, 1004.

Thus, the curve 1006 can have three linear ranges as described above in conjunction with FIG. 5. The curve 1006 can be a result of the magnetoresistance element 100 of FIG. 1 having a yoke shape with a width of one micron and free layer structure magnetic fields of seventy-five Oersteds as described above in conjunction with FIG. 5.

Referring now to FIG. 11, a graph 1100 includes a first curve 1102 indicative of a resistance transfer function of the first portion 102 of FIG. 1. The graph 1100 also includes a second curve 1104 indicative of a resistance transfer function of the second portion 104 of FIG. 1. The graph 1100 also includes a third curve 1106 indicative of a resistance transfer function of the first portion 102 and the second portion 104 taken together in series, i.e., the entire magnetoresistance element 100 of FIG. 1.

The curve 1102 has a center point 1102a midway along a linear portion of the curve 1102. The curve 1104 has a center point 1104a midway along a linear portion of the curve 1104.

An arrow 1108 is indicative of a separation (offset) of the center points 1102a, 1104a. The separation 1108 is larger than the separation 1008 of FIG. 10.

Arrows 1110, 1112 are indicative of linear regions of the curves 1102, 1104, respectively. The linear regions of the first and second curves 1102, 1104 have no overlap, but are close to each other or touch.

An arrow 1111 is indicative of one linear range or region of the curve 1106. The linear region of the curve 1106 can have sensitivity contributions from the two curves 1102, 1104 one at a time, and not combined. Thus, a slope, i.e., a sensitivity, of the curve 1106 can be the same as a slope of the first and second curves 1102, 1104.

The curve 1106 can have one wide linear range as described above in conjunction with FIG. 6. The curve 1106 can be a result of the magnetoresistance element 110 of FIG. 1 having a yoke shape with a width of 2.6 microns and free layer structure magnetic fields of seventy-five Oesrsteds as described above in conjunction with FIG. 6.

Referring now to FIG. 12, a graph 1200 includes a first curve 1202 indicative of a resistance transfer function of the first portion 102 of FIG. 1. The graph 1200 also includes a second curve 1204 indicative of a resistance transfer function of the second portion 104 of FIG. 1. The graph 1200 also includes a third curve 1206 indicative of a resistance transfer function of the first portion 102 and the second portion 104 taken together in series, i.e., the entire magnetoresistance element 100 of FIG. 1.

The curve 1202 has a center point 1202a midway along a linear portion of the curve 1202. The curve 1204 has a center point 1204a midway along a linear portion of the curve 1204.

An arrow 1208 is indicative of a separation (offset) of the center points 1202a, 1204a. The separation 1208 is larger than the separation 1108 of FIG. 11.

An arrow 1210 is indicative of a linear range of the first curve 1202. An arrow 1212 is indicative of a linear range of the second curve 1204. Linear ranges of the first and second curves 1202, 1204 do not overlap.

An arrow 1214 is indicative of one linear range or region of the curve 1206. The linear region of the curve 1206 can have sensitivity contributions from the two curves 1202, 1204 one at a time, and not combined. Thus, a slope, i.e., a sensitivity, of the curve 1206 can be the same as a slope of the first and second curves 1202, 1204.

The curve 1206 has first and second linear regions 1206a, 1206b, respectively. Slopes, i.e., sensitivities, within the first and second linear regions 1206a, 1206b, can be the same the slopes of the linear regions of curves 1202, 1204.

The curve 1206 can have two linear ranges as shown above in conjunction with FIG. 7. The curve 1206 can be a result of the magnetoresistance element 100 of FIG. 1 having a yoke shape with a width of ten microns and free layer structure magnetic fields of seventy-five Oesrsteds as described above in conjunction with FIG. 7.

Referring again to FIGS. 9-12 in combination with FIG. 8, it should be understood that, for relatively large bias magnetic fields, as in FIGS. 11 and 12, at zero external magnetic field, response curves 1102 and 1202 are saturated high and curves 1104, 1204 are saturated low. Thus, in FIGS. 11 and 12 the bias magnetic fields experienced by respective free layers are high enough to move the magnetizations in the free layer structures toward directions of the bias magnetic fields, i.e., in the transverse direction (see, e.g., FIG. 2). However, referring to FIGS. 9 and 10, at zero external field, curves 902, 904, 1002 and 1004 are not saturated. Therefore, for FIGS. 9 and 10, a demagnetizing field (generally in the transverse direction) is strong relative to the bias magnetic fields (generally in the transverse direction) and the demagnetizing field tends to move the magnetizations in the free layer structures to be non-parallel to the bias magnetic field directions.

While embodiments described herein use the dual double pinned magnetoresistance element 100 of FIG. 1, it should be appreciated that the same or similar structures and techniques apply to separate double pinned magnetoresistance elements, for which one of the separate double pinned magnetoresistance elements is the same as or similar to the first portion 102 and the other one of the separate double pinned magnetoresistance elements is the same as or similar to the second portion 104. Same or similar structures can also apply to TMR element, for which the smallest dimension parallel to a substrate can be used in place of the yoke widths above.

All references cited herein are hereby incorporated herein by reference in their entirety.

Having described preferred embodiments, which serve to illustrate various concepts, structures and techniques, which are the subject of this patent, it will now become apparent that other embodiments incorporating these concepts, structures and techniques may be used. Accordingly, it is submitted that the scope of the patent should not be limited to the described embodiments but rather should be limited only by the spirit and scope of the following claims. Elements of embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. A magnetoresistance element disposed upon a substrate, the magnetoresistance element comprising:
a stack of layers, comprising:
a first portion, comprising:
a first bias layer structure for generating a first bias magnetic field with a first bias direction; and
a first free layer structure disposed proximate to the first bias layer structure, wherein the first free layer structure is biased by the first bias magnetic field; and
a second portion, comprising:
a second bias layer structure for generating a second bias magnetic field with a second bias direction; and
a second free layer structure disposed proximate to the second bias layer structure, wherein the second free layer structure is biased by the second bias magnetic field, wherein the first bias direction and the second bias directions are opposite to each other, and wherein the magnetoresistance element further comprises:
a shape having a longest dimension and a shortest dimension both parallel to the substrate, wherein the first and second bias magnetic fields are within +/− twenty-five degrees of parallel to the shortest dimension.

2. The magnetoresistance element of claim 1, wherein the first portion comprises a first resistance-to-external-magnetic-field transfer function having a first linear range over external magnetic fields and wherein the second portion comprises a second resistance-to-external-magnetic-field transfer function having a second linear range over external magnetic fields, the first and second linear ranges having an overlap in a direction of external magnetic fields less than eighty-five percent of the first linear range and less than eighty-five percent of the second linear range and wherein the magnetoresistance element further comprises:
a third resistance-to-external-magnetic-field transfer function different than the first and second resistance-to-external-magnetic-field transfer functions.

3. The magnetoresistance element of claim 2, wherein a combination of the shortest dimension and magnitudes of the first and second bias magnetic fields is selected to result in the overlap.

4. The magnetoresistance element of claim 2, wherein the second portion is disposed under the first portion in a direction perpendicular to a major surface of the substrate.

5. The magnetoresistance element of claim 2, wherein the shortest dimension and magnitudes of the first and second bias magnetic fields are selected to result in the third resistance-to-external-magnetic-field transfer function having first, second, and third linear regions, the first linear region associated with a first range of external magnetic fields, the second linear region associated with a second range of external magnetic fields, and the third linear region associated with a third range of external magnetic fields, the first, second, and third ranges being different ranges, a center of the second range between the first and third ranges.

6. The magnetoresistance element of claim 5, wherein the second linear region has a slope greater than one hundred fifty percent of slopes of the first and third linear regions.

7. The magnetoresistance element of claim 5, wherein the shape comprises a yoke shape.

8. The magnetoresistance element of claim 5, wherein the second portion is disposed under the first portion in a direction perpendicular to a major surface of the substrate.

9. The magnetoresistance element of claim 2, wherein the shortest dimension and magnitudes of the first and second bias magnetic fields are selected to result in the third resistance-to-external-magnetic-field transfer function having a linear region greater than one hundred fifty percent of the first linear range of the first resistance-to-external-magnetic-field transfer function and also greater than one hundred fifty percent of the second linear range of the second resistance-to-external-magnetic-field transfer function.

10. The magnetoresistance element of claim 9, wherein the third resistance-to-external-magnetic-field transfer function has only one linear region.

11. The magnetoresistance element of claim 9, wherein the shape comprises a yoke shape.

12. The magnetoresistance element of claim 9, wherein the second portion is disposed under the first portion in a direction perpendicular to a major surface of the substrate.

13. The magnetoresistance element of claim 2, wherein the shortest dimension and magnitudes of the first and second bias magnetic fields are selected to result in the third resistance-to-external-magnetic-field transfer function having first and second linear regions, the first linear region associated with a first range of external magnetic fields and the second linear region associated with a second range of external magnetic fields, the first and second linear ranges being different and non-overlapping linear ranges,

14. The magnetoresistance element of claim 13 wherein the first and second linear regions have equal slopes.

15. The magnetoresistance element of claim 13, wherein the shape comprises a yoke shape.

16. The magnetoresistance element of claim 13, wherein the second portion is disposed under the first portion in a direction perpendicular to a major surface of the substrate.

17. The magnetoresistance element of claim 1, wherein the second portion is disposed under the first portion in a direction perpendicular to a major surface of the substrate.
